(19) United States
(12) Patent Application Publication
(10) Pub. No.: US 2025/0366024 A1
(43) Pub. Date: Nov. 27, 2025

(54) SUPER-JUNCTION SEMICONDUCTOR DEVICE AND MANUFACTURING METHOD THEREOF

(71) Applicant: Magnachip Semiconductor, Ltd., Cheongju-si (KR)

(72) Inventors: Kihwan KIM, Seoul (KR); Jiyong LIM, Seoul (KR); Suyoung MOON, Gwacheon-si (KR); Jaehyeon JUNG, Gumi-si (KR); Jinseong HAN, Seoul (KR); Kitae KANG, Gumi-si (KR); Seongchan JEON, Gumi-si (KR)

(73) Assignee: Magnachip Semiconductor, Ltd., Cheongju-si (KR)

(21) Appl. No.: 19/097,824

(22) Filed: Apr. 1, 2025

(30) Foreign Application Priority Data
May 23, 2024 (KR) 10-2024-0067107
Dec. 30, 2024 (KR) 10-2024-0201302

(51) Int. Cl. H10D 30/66; H10D 30/01; H10D 62/10; H10D 62/60; H10D 64/00

(52) U.S. Cl. CPC H10D 30/665; H10D 30/0291; H10D 30/662; H10D 62/106; H10D 62/124; H10D 62/60; H10D 64/111

(57) ABSTRACT

A super junction semiconductor device includes a substrate; a plurality of epitaxial layers disposed on the substrate; an active region disposed on one region of the substrate and the epitaxial layer; a peripheral region and an edge termination region surrounding the active region; and a plurality of first conductive type pillar regions and a plurality of second conductive type pillar regions disposed in the plurality of epitaxial layers, respectively. Each of the plurality of first conductive type pillar regions and the plurality of second conductive type pillar regions in the active region is divided into a lower pillar region, an intermediate pillar region, and an upper pillar region, sequentially. A dopant concentration gradually increases from the lower pillar region to the intermediate pillar region, and another dopant concentration gradually decreases from the intermediate pillar region to the upper pillar region.

### CROSS REFERENCE TO RELATED APPLICATIONS

The application claims the benefit under 35 USC 119(a) of Korean Patent Application Nos. 10-2024-0201302, filed Dec. 30, 2024, and 10-2024-0067107, filed May 23, 2024, in the Korean Intellectual Property Office, the entire disclosures of which are incorporated herein by reference for all purposes.

### BACKGROUND

### 1. Field

The following description relates to a super-junction semiconductor device and manufacturing method thereof.

### 2. Description of the Background

A super junction MOSFET among electric semiconductor devices is a semiconductor device capable of securing a low on-resistance and a high breakdown voltage by alternately forming an n-pillar or an n-drift region and a p-pillar region vertically within an epitaxial layer formed on a substrate.

The super junction MOSFET device may be applied to various applications such as a DC-DC converter, an inverter, an LLC converter, and the like. In order to apply it to such various applications, robustness and ruggedness of di/dt values, which are slope values of a reverse recovery current of a body diode inside the device must be secured while characteristics of a forward voltage, a breakdown voltage, and on-resistance are secured at the same time. If the slope value of the reverse recovery current of the diode cannot be secured, the device may be destroyed due to a high reverse voltage and a high reverse current during a reverse recovery operation of the body diode formed inside the super junction MOSFET device, and because of this, a problem may occur in the device reliability.

The super junction MOSFET device is formed of an active region, an edge termination region, and a peripheral region disposed between the active region and the edge termination region. In particular, a burned mark phenomenon attributable to the destruction of the device occurs the most frequently in the peripheral region of a corner region which is an end side of the super junction MOSFET device, and this occurs because a hole current concentrates around the corner of the peripheral region. In order to prevent this phenomenon, the conventional technology has used a method for reducing a hole carrier by additionally implementing a Schottky diode, or a method for reducing a hole carrier lifetime through helium irradiation or electron beam irradiation, however, these methods increase a leakage current or an on-resistance, thereby influencing device characteristics and increasing processing expenses.

In order to prevent the above-described phenomenon, it may be desirable to improve the robustness and ruggedness of slope values of the reverse recovery current of the body diode in the peripheral region and the edge termination region disposed in the super junction MOSFET device by optimizing a hole current path during the reverse recovery.

An initial value of an output capacitor of the super junction MOSFET device is great due to high cell density, however, the value dramatically decreases at a drain-source voltage of a certain level or more. Due to the non-linear characteristic of the output capacitor, a gate oscillation may occur, and this may cause a switching loss to increase or to be out of a normal controllable range.

It may be desirable to ease the gate oscillation at the time of the switching operation by preventing a fast expansion of the n-pillar depletion layer so as to prevent the phenomenon.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a superjunction semiconductor device includes a substrate; a plurality of epitaxial layers disposed on the substrate; an active region disposed on one region of the substrate and the epitaxial layer; a peripheral region and an edge termination region surrounding the active region; and a plurality of first conductive type pillar regions and a plurality of second conductive type pillar regions disposed in the plurality of epitaxial layers, respectively. Each of the plurality of first conductive type pillar regions and the plurality of second conductive type pillar regions in the active region is divided into a lower pillar region, an intermediate pillar region, and an upper pillar region, sequentially. A dopant concentration gradually increases from the lower pillar region to the intermediate pillar region, and another dopant concentration gradually decreases from the intermediate pillar region to the upper pillar region.

A dopant concentration of the lower pillar region of the first conductive type pillar region may be greater than a dopant concentration of the upper pillar region of the first conductive type pillar region. A dopant concentration of the lower pillar region of the second conductive type pillar region may be greater than a dopant concentration of the upper pillar region of the second conductive type pillar region.

Each of the lower pillar region of the first conductive type pillar region and the lower pillar region of the second conductive type pillar region may be divided into a lower pillar layer, an intermediate pillar layer, and an upper pillar layer. A dopant concentration of the lower pillar layer of the lower pillar region of the first conductive type pillar region may be lower than a dopant concentration of the intermediate pillar layer of the lower pillar region of the first conductive type pillar region. Dopant concentrations of the lower pillar layer, the intermediate pillar layer, and the upper pillar layer of the lower pillar region of the second conductive type pillar region may be the same.

Each of the intermediate pillar region of the first conductive type pillar region and the intermediate pillar region of the second conductive type pillar region may be divided into a lower pillar layer, an intermediate pillar layer, and an upper pillar layer. A dopant concentration of the intermediate pillar layer of the intermediate pillar region of the first conductive type pillar region may be greater than a dopant concentration of the lower pillar layer and the upper pillar layer of the intermediate pillar region of the first conductive type pillar region. A dopant concentration of the intermediate pillar layer of the intermediate pillar region of the second conductive type pillar region may be greater than the lower pillar layer and the upper pillar layer of the intermediate pillar region of the second conductive type pillar region.

The superjunction semiconductor device may further include a second conductive type charge-sharing region, formed in the peripheral region and the edge termination region, connected to the upper pillar region in the second conductive type pillar region.

The upper pillar region of the first conductive type pillar region and the upper pillar region of the second conductive type pillar region may be divided into a lower pillar layer and an upper pillar layer. The upper pillar layer of the upper pillar region of the second conductive type pillar region in the active region may include a second conductive type body region. A dopant concentration of the lower pillar layer of the upper pillar region of the first conductive type pillar region and the second conductive type pillar region may be greater than a dopant concentration of the upper pillar layer of the upper pillar region of the first conductive type pillar region and the second conductive type pillar region.

A thickness of the upper pillar layer of the upper pillar region of the first conductive type pillar region and the second conductive type pillar region may be greater than a thickness of the lower pillar layer of the upper pillar region of the first conductive type pillar region and the second conductive type pillar region.

A width of the upper pillar layer of the upper pillar region of the second conductive type pillar region in a boundary portion between the edge termination region and the peripheral region may be greater than a width of the upper pillar layer of the upper pillar region of the second conductive type pillar region in the active region.

In another general aspect, a method for manufacturing a super junction semiconductor device includes forming a lower pillar region by forming a plurality of lower epitaxial layers on a semiconductor substrate having an active region, a peripheral region, and an edge termination region, and by alternately forming a first conductive type pillar and a second conductive type pillar through a first ion injection process within the plurality of lower epitaxial layers; forming an intermediate pillar region of a first conductive type pillar and a second conductive type pillar in the lower pillar region by forming a plurality of intermediate epitaxial layers on the plurality of lower epitaxial layers, and conducting a second ion injection process within the plurality of intermediate epitaxial layers; and forming an upper pillar region of a first conductive type pillar and a second conductive type pillar in the intermediate pillar region by forming a plurality of upper epitaxial layers on the plurality of intermediate epitaxial layers and conducting a third ion injection process within the plurality of upper epitaxial layers. A dopant concentration of the intermediate pillar region is greater than a dopant concentration of the lower pillar region and a dopant concentration of the upper pillar region.

The method may further include forming an ion injection region on the upper pillar region of the first conductive type pillar and the second conductive type pillar formed in the edge termination region; forming an ion injection region on the upper pillar region of the first conductive type pillar and the second conductive type pillar formed in the peripheral region; and forming a charge-sharing region by dispersing the ion injection region in each of the edge termination region and the peripheral region.

The forming of the lower pillar region may include forming a lower pillar layer, an intermediate pillar layer, and an upper pillar layer in the lower pillar region and allowing a dopant concentration of the intermediate pillar layer to be greater than a dopant concentration of the lower pillar layer.

The forming of the intermediate pillar region may include forming a lower pillar layer, an intermediate pillar layer, and an upper pillar layer in the intermediate pillar region and allowing a dopant concentration of the intermediate pillar region to be greater than dopant concentrations of the lower pillar layer and the upper pillar layer.

The method may further include allowing a dopant concentration of the upper pillar layer to be greater than a dopant concentration of the lower pillar layer.

The forming of the upper pillar region may include forming a lower pillar layer and an upper pillar layer on the upper pillar region and allowing a dopant concentration of the lower pillar layer to be greater than a dopant concentration of the upper pillar layer.

The forming of the lower pillar layer and the upper pillar layer on the upper pillar region may include forming a thickness of the lower pillar layer to be thicker than a thickness of the upper pillar layer.

The forming of the lower pillar layer and the upper pillar layer on the upper pillar region may include forming a mask on the lower pillar layer; forming a plurality of openings by patterning the mask in the active region, the peripheral region, and the edge termination region, and forming an area of the plurality of openings in a boundary portion between the peripheral region and the edge termination region to be greater than an area of the plurality of openings of the active region; and forming a width of the upper pillar layer of a second conductive type in the edge termination region and the peripheral region to be greater than a width of the upper pillar layer of a second conductive type in the active region by conducting the second ion injection process within the plurality of openings.

The forming of the lower pillar region may include forming an epitaxial layer on which the lower pillar region is formed as an intrinsic epitaxial layer. The forming of the intermediate pillar region may include forming an epitaxial layer on which the intermediate pillar region is formed as an intrinsic epitaxial layer. The forming of the upper pillar region may include forming an epitaxial layer of which the upper pillar region allows the lower pillar layer and the upper pillar layer to be formed thereon as an intrinsic epitaxial layer.

In another general aspect, a super junction semiconductor device includes a substrate; a plurality of epitaxial layers formed on the substrate; and a plurality of first conductive type pillars and a plurality of second conductive type pillars formed perpendicular to the substrate within the plurality of the epitaxial layers, and alternately disposed in a horizontal direction with respect to the substrate. The plurality of epitaxial layers are divided into a lower pillar region, an intermediate pillar region, and an upper pillar region. A thickness of one epitaxial layer of the plurality of epitaxial layers in the upper pillar region is greater than a thickness of another epitaxial layer of the plurality of epitaxial layers in the upper pillar region.

The lower pillar region may be divided into a lower pillar layer, an intermediate pillar layer, and an upper pillar layer each formed of a plurality of epitaxial layers. A thickness of the lower pillar layer may be greater than thicknesses of the intermediate pillar layer and the upper pillar layer.

The intermediate pillar region may be divided into a lower pillar layer, an intermediate pillar layer, and an upper pillar layer each formed of a plurality of epitaxial layers. Thicknesses of the lower pillar layer, the intermediate pillar layer and the upper pillar layer may be the same.

Other features and aspects will be apparent from the following detailed description, the drawings, and the claims.

### BRIEF DESCRIPTION OF DRAWINGS

FIG. 1 is a plan view of a super junction semiconductor device according to an embodiment of the present disclosure.

FIG. 2 is an enlarged plan view of a portion of a super junction semiconductor device according to an embodiment of the present disclosure.

FIG. 3a is a cross-sectional view taken along X-X′ line in FIG. 2 of a super junction semiconductor device.

FIG. 3b is an enlarged cross-sectional view of a portion of an active region in FIG. 3a.

FIG. 3c is an enlarged cross-sectional view of an upper region of a peripheral region and an edge determination region of FIG. 3a.

FIGS. 4 to 25 are views illustrating a series of processes for manufacturing a super junction semiconductor device according to an embodiment of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

A term “part” or “module” used in the embodiments may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may include components such as software components, object-oriented software components, class components, and task components, and may include processes, functions, attributes, procedures, subroutines, segments of a program code, drivers, firmware, microcode, circuits, data, databases, data structures, tables, arrays, and variables. Components and functions provided in the “part” or “module” may be combined with a smaller number of components and “parts” or “modules” or may be further divided into additional components and “parts” or “modules”.

Methods or algorithm steps described relative to some embodiments of the present enclosures may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the storage medium may reside in an application specific integrated circuit (ASIC). The ASIC may be resident within a user's terminal.

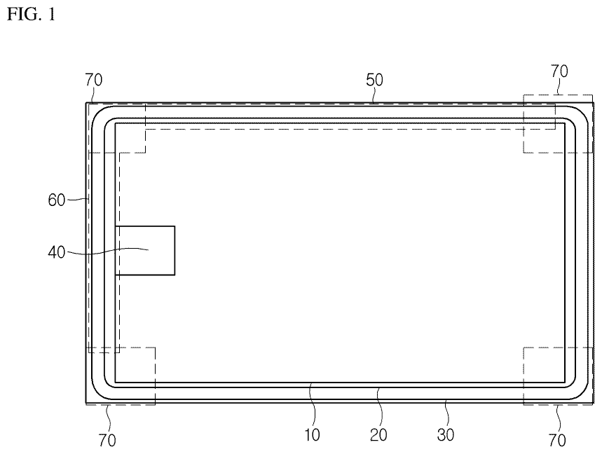

FIG. 1 is a plan view of a super junction semiconductor device according to an embodiment of the present disclosure.

Referring to FIG. 1, the super junction semiconductor device may include an active region 10, an edge termination region 30, and a peripheral region 20. In the super junction semiconductor device, the cell region which is the active region 10 may be formed at the center thereof, and the edge termination region 30 surrounding the active region 10, and the peripheral region 20 disposed between the active region 10 and the edge termination region 30 may be formed.

A gate pad 40 may be formed in the active region 10.

The edge termination region 30 and the peripheral region 20 may be divided into different regions. According to an embodiment, the edge termination region 30 and the peripheral region 20 may be divided into edge/peripheral top and bottom regions 50 disposed upward and downward of the active region 10, edge/peripheral side regions 60 disposed on both sides of the active region 10, and an edge/peripheral corner region 70 connecting edge/peripheral top and bottom regions 50 and the side regions 60 to each other, based on the active region 10.

A charge-sharing region may be formed in the edge termination region 30 and the peripheral region 20. The charge-sharing region may have a ring shape in the edge termination region, and may have a characteristic that the charge-sharing region can be formed only in some region in the peripheral region 20.

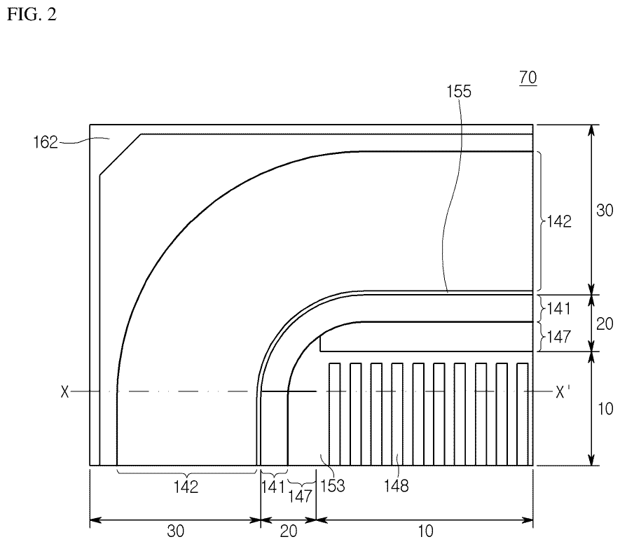

FIG. 2 is an enlarged plan view of the peripheral/edge termination corner region of the super junction semiconductor device according to an embodiment of the present disclosure.

Referring to FIG. 2, the super junction semiconductor device may be divided into the active region 10, the edge termination region 30, and the peripheral region 20 disposed between the active region 10 and the edge termination region 30.

The edge termination region 30 may include a guard ring region (or referred to as a floating electrode) 162, an edge termination charge-sharing region 142, and a field plate 155. In the field plate 155, a gate runner may be formed, and the gate runner may be connected to a gate pad.

The peripheral region 20 may include a peripheral charge-sharing region 141, and a peripheral contact region 147. A source electrode may be formed in the peripheral contact region 147. The peripheral contact region 147 may be connected to a source contact region 148 disposed in the active region 10 through the source electrode.

The charge-sharing regions 141 and 142 may be formed in some of the edge termination region 30 and the peripheral region 20. The charge-sharing regions 141 and 142 may be dividedly referred to as the edge termination charge-sharing region 142 formed in the edge termination region 30, and the peripheral charge-sharing region 141 formed in the peripheral region 20. The charge-sharing regions 141 and 142 may be formed by disposing a mask on the epitaxial layer, exposing a portion where the charge-sharing regions 141 and 142 are formed on the epitaxial layer through a mask etching process, and conducting an ion injection process on the exposed epitaxial layer.

A plurality of pillar regions may be formed below a gate electrode 153 and the source contact region 148.

The edge termination region 30 may include the guard ring region (the floating electrode) 162, the edge termination charge-sharing region 142, and the field plate 155. The peripheral region 20 may include the peripheral charge-sharing region 141 and the peripheral contact region 147. The active region 10 may be surrounded by the peripheral region 20 and the edge termination region 30.

The charge-sharing regions 141 and 142 may be formed by expanding from the edge termination region 30 to the peripheral region 20.

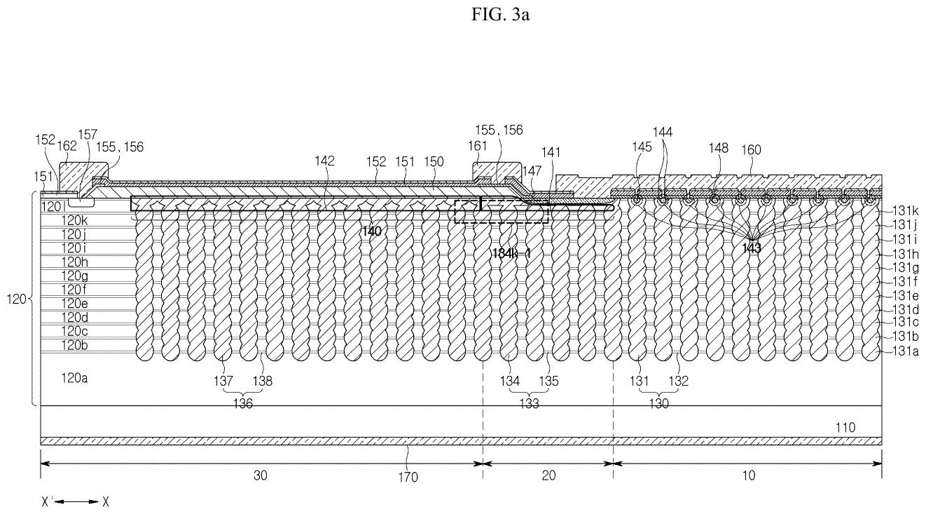

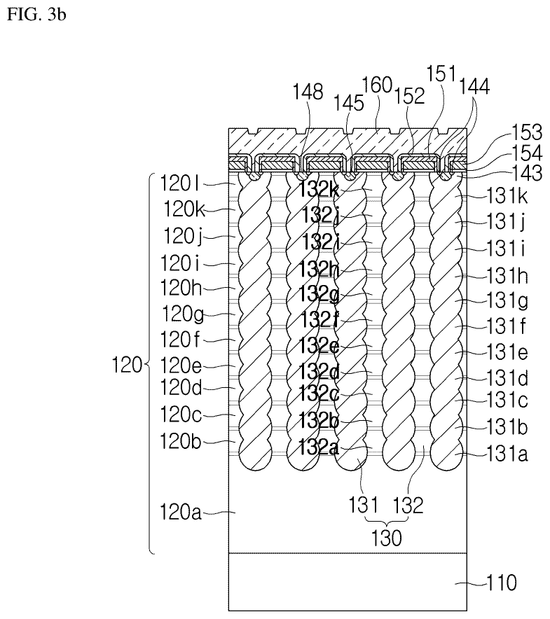

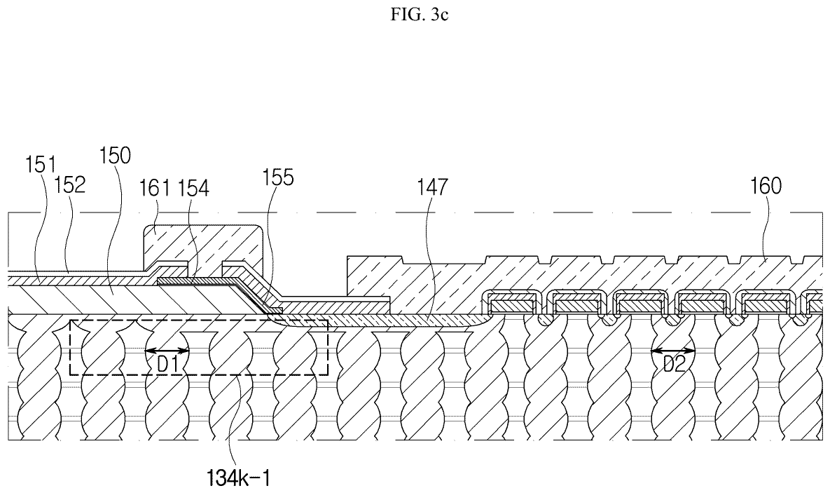

FIG. 3a is a cross-sectional view taken along X-X′ line in FIG. 2 of a super junction semiconductor device.

FIG. 3b is an enlarged cross-sectional view of a first conductive type pillar region and a second conductive type pillar region in the active region in FIG. 3a.

FIG. 3c is an enlarged cross-sectional view of an upper region of a pillar region of a second conductive type of the peripheral region and the edge determination region of FIG. 3a.

Referring to FIG. 3a, the super junction semiconductor device may include the active region 10, the peripheral region 20, and the edge termination region 30. An epitaxial layer 120 may be formed on the substrate 110 of the super junction semiconductor device, and a drain electrode 170 may be formed below the substrate 110.

The epitaxial layer 120 may be a region in which an impurity of the first conductive type is doped. A plurality of pillar regions may be formed in the epitaxial layer 120. The pillar regions may be divided into a first pillar region 130 formed in the active region 10, a second pillar region 133 formed in the peripheral region 20, and a third pillar region 136 formed in the edge termination region 30.

The epitaxial layer 120 may be formed by stacking a plurality of layers, and according to an embodiment, the layers may be divided into lower layers 120a to 120c, intermediate layers 120d to 120i, and upper layers 120j to 120l. In this instance, a dopant concentration of the p-type and the n-type of the intermediate layers 120d to 120i may be formed to be greater than a dopant concentration of the p-type and the n-type of the lower layers 120a to 120c. As such, the differentiation of the dopant concentrations per layer may ease the gate oscillation at the time of switching operation by preventing fast expansion of a first conductive type depletion layer while maintaining the existing basis of the pillars which is improving productivity. The quantity of layers stacked so as to form the epitaxial layer 120 is not limited to what is illustrated in FIG. 3, but may be n, which is an integer equal to or more than 1. The quantity of the lower layer, the intermediate layer, and the lower layer may be n1, n2, n3(n1+n2+n3=N), each of which is an integer equal to or more than 1.

A first n-type pillar 132 and a first p-type pillar 131 may be divided according to the quantity of the epitaxial layer. First n-type and first p-type lower pillar regions 131a to 131c and 132a to 132c may be disposed in lower epitaxial layers 120a to 120c, first n-type and first p-type intermediate pillar regions 131d to 131i and 132d to 132i may be disposed in intermediate epitaxial layers 120d to 120i, and first n-type and first p-type upper pillar regions 131j to 131k and 132j to 132k may be disposed in upper epitaxial layers 120j to 120l.

When dividing the lower epitaxial layers 120a to 120c in more detail, the lower epitaxial layers 120a to 120c may be divided into a lower layer 120a, an intermediate layer 120b, and an upper layer 120c.

When dividing the intermediate epitaxial layers 120d to 120i in more detail, the intermediate epitaxial layers 120d to 120i may be divided into a lower layer 120d, intermediate layers 120e to 120h, and an upper layer 120i.

When dividing the upper epitaxial layers 120j to 120l in more detail, the upper epitaxial layers 120j to 120l may be divided into a lower layer 120j, an intermediate layer 120k, and an upper layer 120l.

Each of the layers of the epitaxial layer 120 may be formed through an ion injection process of injecting a dopant into an intrinsic epitaxial layer or a non-doped epitaxial layer, and this method may reduce variation of a process compared to a conventional method of using a doped epitaxial layer.

According to an embodiment, the epitaxial layer 120 may be formed by conducting a sub-epitaxial layer deposition of the first epitaxial layer 120a to the twelfth epitaxial layer 120l twelve times, or a multi-epitaxial growth process. In this instance, a thickness of each of the epitaxial layers may be represented by a ratio with respect to the overall epitaxial layer 120. A thickness of the first epitaxial layer 120a may be about 28.5%, a thickness of the second to tenth epitaxial layer 120b to 120j may be about 6.45%, and a thickness of the eleventh epitaxial layer 120k may be about 7%, and a thickness of the twelfth epitaxial layer 120l may be about 6.45%, each of which with respect to a thickness of the overall epitaxial layer 120. Forming the eleventh epitaxial layer 120k thicker than nearby epitaxial layers may be for the sake of easing the gate turn-off oscillation by increasing the ripple of the pillars and reducing dv/dt of the device. In this instance, when increasing the ripple of all pillars, the on-resistance R_{DSON} between the drain and the source of the MOSFET may increase, and the processing margin may be reduced, therefore, as illustrated in the example of FIG. 3, a thickness of the eleventh epitaxial layer 120k only is differentiated so that the ripple can be increased. Alternatively, the ripple may be increased by differentiating the thickness of a plurality of sub-epitaxial layers. For example, a thickness of the tenth epitaxial layer 120j or a thickness of the tenth epitaxial layer 120j to the ninth epitaxial layer 120i may be increased the same as that of the eleventh epitaxial layer 120k.

Referring to FIG. 3b, the first pillar region 130 may include a plurality of first conductive type pillars (e.g., n-type) and second conductive type pillars (e.g., p-type). The second conductive type pillar in the first pillar region may be a first p-type pillar 131 in which a p-type impurity is doped, and the first conductive type pillar may be a first n-type pillar 132 in which an n-type impurity is doped. The first p-type pillar 131 may be formed between a first n-type pillar 132 and another first n-type pillar 132. A second conductive type body region 143 may be formed on the first p-type pillar 131. The first p-type pillar 131 and the body region 143 may be connected to each other in the structure. A first conductive type source region 144 may be formed in the body region 143. A second conductive type body contact region 145 may be formed between the source regions 144. The body contact region 145 may be formed on a surface of the epitaxial layer 120.

As described above, the first n-type pillar 132 and the first p-type pillar 131 may be formed by injecting different dopant concentrations into each of the epitaxial layers. This method can maintain a proper breakdown voltage and reduce process variation by creating a charge balance.

The lower epitaxial layers 120a to 120c of the first n-type pillar 132 may be divided into first n-type lower pillar regions 132a to 132c, and a concentration value of the first n-type lower pillar region in percent may be set in a range of more than 50% and equal to or less than 90%. The first n-type lower pillar regions 132a to 132c may be divided into an n-type lower-lower pillar region 132a, an n-type lower-intermediate pillar region 132b, and an n-type lower-upper pillar region 132c. A concentration value of the n-type lower-lower pillar region 132a in percent may be set in a range more than 50% and equal to or less than 60%. In addition, concentration values of the n-type lower-intermediate pillar region 132b and the n-type lower-upper pillar region 132c in percent may be set in a range of more than 80% and equal to or less than 90%.

The intermediate epitaxial layers 120d to 120i of the first n-type pillar 132 may be divided into the first n-type intermediate pillar regions 132d to 132i, and concentration values of the first n-type intermediate pillar regions 132d to 132i in percent may be set in a range of more than 100% and equal to or less than 120%. The first n-type intermediate pillar regions 132d to 132i may be divided into an n-type intermediate-lower pillar region 132d, n-type intermediate-intermediate pillar regions 132e to 132h, and an n-type intermediate-upper pillar region 132i. A concentration value of the n-type intermediate-lower pillar region 132d in percent may be set in a range of more than 100% and equal to or less than 110%. In addition, a concentration value of the n-type intermediate-intermediate pillar region 132e to 132h in percent may be set in a range of more than 110% and equal to or less than 120%. A concentration value of the n-type intermediate-upper pillar region 132i in percent may be set in a range of more than 100% and equal to or less than 110%.

The upper epitaxial layers 132j to 132k of the first n-type pillar 132 may be divided into the first n-type upper pillar regions 132j to 132k. The first n-type upper pillar regions 132j to 132k may be divided into an n-type upper-lower pillar layer 132j, and an n-type upper-upper pillar layer 132k. A concentration value of the n-type upper-lower pillar layer 132j in percent may be set in a range more than 70% and equal to or less than 80%, and a concentration value of the n-type upper-upper pillar layer 132k in percent may be set in a range more than 50% and equal to or less than 60%.

The concentration value of the n-type upper-upper pillar layer 132k is relatively lower than the concentration value of the n-type upper-lower pillar layer 132j, and the electric field concentrated on a surface of the epitaxial layer may be eased through the n-type upper-upper pillar layer 132k and the n-type upper-lower pillar layer 132j. On the n-type upper-upper pillar layer 132k, the second conductive type body region, the source region, and the like may be formed, and the ion of a lower concentration may be injected thereinto.

The lower epitaxial layers 120a to 120c of the first p-type pillar 131 may be divided into the first p-type lower pillar regions 131a to 131c where concentration values of the first p-type lower pillar regions 131a to 131c in percent may be set in a range of more than 80% and equal to and less than 90%. The first p-type lower pillar regions 131a to 131c may be divided into a p-type lower-lower pillar layer 131a, a p-type lower-intermediate pillar layer 131b, and a p-type lower-upper pillar layer 131c, where concentration values of the p-type lower-lower pillar layer 131a, the p-type lower-intermediate pillar layer 131b, and the p-type lower-upper pillar layer 131c of the first p-type lower pillar regions are the same.

The intermediate epitaxial layers 120d to 120i of the first p-type pillar 131 may be divided into the first p-type intermediate pillar region 131d to 131i where concentration values of the first p-type intermediate pillar regions 131d to 131i in percent may be set in a range more than 100% and equal to or less than 120%. The first p-type intermediate pillar regions 131d to 131i may be divided into a p-type intermediate-lower pillar layer 131d, p-type intermediate-intermediate pillar layers 131e to 131h, and a p-type intermediate-upper pillar layer 131i. A concentration value of the p-type intermediate-lower pillar layer 131d may be set in a range of more than 100% and equal to or less than 110%. A concentration value of the p-type intermediate-intermediate pillar layers 131e to 131h may be set in a range of more than 110% and equal to or less than 120%. A concentration value of the p-type intermediate-upper pillar layer 131i may be set in a range of more than 105% and equal to or less than 115%.

The upper epitaxial layers 120j to 120l of the first p-type pillar 131 may be divided into first p-type upper pillar regions 131j to 131k. The first p-type upper pillar regions 131j to 131k may be divided into a p-type upper-lower pillar layer 131j and a p-type upper-upper pillar layer 131k. The second conductive type body region 143 may be formed on the p-type upper-upper pillar layer 131k. A concentration value of the p-type upper-lower pillar region 131j of the first p-type upper pillar regions 131j to 131k may be set in a range of more than 70% and equal to or less than 80%. A concentration value of the p-type upper-upper pillar layer 131k of the first p-type upper pillar regions 131j to 131k may be set in a range of more than 55% and equal to or less than 70%.

Through this configuration, the balance in the amount of the charge in the first n-type pillar region 132 and the first p-type pillar region 131 may be created, thereby becoming able to secure a stable breakdown voltage and reducing the gate turn-off oscillation.

In addition, a second n-type pillar region 135 and a second p-type pillar region 134 in the peripheral region 20, and a third n-type pillar region 138 and a third p-type pillar region 137 in the edge termination region 30 may be formed to have the same concentration as the concentration of the first n-type pillar 132 and the first p-type pillar 131 in the active region.

A gate insulation layer 154 may be formed on the body region 143 and the first n-type pillar region 132 disposed in the active region 10. The gate insulation layer 154 may be formed in one region of the source region 144.

The first n-type pillar region 132 may be referred to as a drift layer.

Referring to FIG. 3b, a gate electrode 153 may be formed in the gate insulation layer 154. A first insulation layer 151 may be formed on a side surface and an upper surface of the gate electrode 153, and a second insulation layer 152 may be formed on the first insulation layer 151.

The source electrode 160 may be formed on the second insulation layer 152 and the body contact region 145, and the source electrode 160 may be in ohmic contact with the body contact region 145.

Referring to FIG. 3a, the second pillar region 133 may be formed in the peripheral region 20. The second pillar region 133 may include a plurality of second n-type pillars 135 and second p-type pillars 134. The second p-type pillar 134 may be formed between a second n-type pillar 135 and another second n-type pillar 135.

Referring to FIGS. 3a and 3c, the gate insulation layer 154 may be formed on an end and a side surface of a field oxide layer 150 and the peripheral charge-sharing region 141 and on a perimeter of the peripheral region 20 in a direction of the peripheral region 20.

Referring to FIG. 3a, the third pillar region 136 may be formed in the edge termination region 30. The third pillar region 136 may include third n-type pillars 138 and third p-type pillars 137. The third p-type pillar 137 may be formed between a third n-type pillar 138 and another third n-type pillar 138.

The charge-sharing region 140 may be formed on a surface of the epitaxial layer 120 in the peripheral region 20 and the edge termination region 30. The charge-sharing region 140 may be a second conductive type (e.g., p-type). The charge-sharing region 142 in the edge termination region 30 and the charge-sharing region 141 in the peripheral region 20 may be formed through an ion injection process and an annealing process. The charge-sharing region 140 in the peripheral region 20 may be referred to as the peripheral charge-sharing region 141, and the charge-sharing region 141 in the edge termination region 30 may be referred to as the edge termination charge-sharing region 142. The peripheral charge-sharing region 141 and the edge termination charge-sharing region 142 may be connected to each other. The peripheral charge-sharing region 141 may be connected to the second p-type pillar 134, and the edge termination charge-sharing region 142 may be connected to the third p-type pillar 137.

Referring to FIGS. 3a and 3c, the peripheral contact region 147 may be formed in the peripheral charge-sharing region 141.

Referring to FIG. 3a, the source electrode 160 may be formed on the peripheral contact region 147 in the peripheral region 20, the body contact region 145, and the source contact region 148 in the active region 10. The source electrode 160 may serve as a metal plate.

The field oxide layer 150 may be formed on the edge termination charge-sharing region 142 in the edge termination region 30 and may be partially formed on the peripheral charge-sharing region in the peripheral region 20.

Referring to FIGS. 3a and 3c, the field plate 155 may be formed on a side wall of the field oxide layer 150. The field plate 155 may be positioned on one end of the field oxide layer 150 in a direction of the peripheral region 20, and may be formed on the field oxide layer 150 and the gate insulation layer 154. The field plate 155 may serve to ease the electric field.

Referring to FIG. 3a, a gate runner 161 may be formed on the field plate 155. The gate runner 161 may be formed simultaneously with the source electrode 160 when the source electrode 160 is formed. The gate runner 161 may be connected to the gate pad along a line of the edge termination region 30.

The guard ring region or the floating electrode 162 may be formed on a tip portion (end portion) of the edge termination region 30.

An edge junction region 157 may be formed in a lower part of the floating electrode 162. The edge junction region 157 may serve as a channel stopper configured to stop the electric field which occurs when a reverse bias is applied.

Referring to FIGS. 3a and 3b, the edge junction region 157 may have the same conductive type as that of the body region 143.

Referring to FIG. 3a, the edge termination charge-sharing region 142 and the peripheral charge-sharing region 141 may be connected to each other, and may be disposed on a surface of the epitaxial layer 120. The charge-sharing regions 141 and 142 formed in the edge termination region 30 and the peripheral region 20 may be referred to as p-top layer regions.

Referring to FIGS. 3a and 3c, below the charge-sharing region 140 disposed on a boundary between the edge termination region 30 and the peripheral region 20, an edge-and-peripheral boundary top pillar region 134k-1 of the second conductive type is disposed. A width D1 of the edge-and-peripheral boundary top pillar region 134k-1 of the second conductive type is formed to be greater than a width of the upper pillar layer 131k in the active region, and therefore, the injected ion and density of the upper pillar region 131k in the active region 10 may be higher. This may distribute a hole current generated when the reverse bias is applied in the edge termination region 30, thereby improving the ruggedness of the device and preventing a lattice temperature on a boundary between the edge termination region and the peripheral region from increasing.

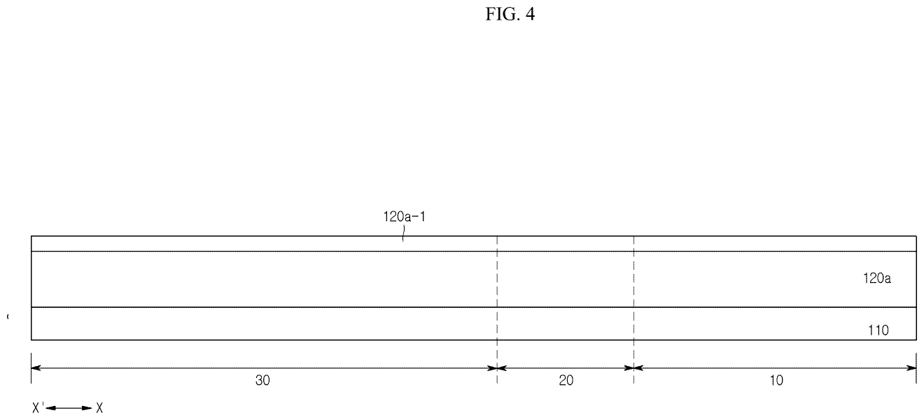

FIGS. 4 to 25 are views illustrating a series of processes for manufacturing the super junction semiconductor device according to an embodiment of the present disclosure.

Referring to FIG. 4, the active region 10, the peripheral region 20, and the edge termination region 30 may be disposed on the substrate 110.

A multi-epitaxial process for forming a plurality of epitaxial layers on the substrate 110 may be conducted.

First, a first epitaxial layer 120a may be formed on the substrate 110.

The substrate 110 is an n-type doped semiconductor substrate, and the first epitaxial layer 120 may be the n-type doped epitaxial layer as well. The first epitaxial layer 120a may be formed through an epitaxial process using materials such as PH3 (phosphine), AsH3 (arsine) and the like, and may be formed to be an intrinsic epitaxial layer.

When representing a thickness of the first epitaxial layer 120a with respect to the overall epitaxial layer 120, the thickness may be formed with a ratio of about 27.5% to about 29.5% with respect to the overall epitaxial layer 120.

It is possible to additionally inject a dopant of the first conductive type (e.g., n-type) into the first epitaxial layer 120a, and this may be referred to as an n-type blanket ion injection process. It is possible to increase the concentration of the ions of the first conductive type on the surface of the first epitaxial layer 120a-1 by injecting ions into the first epitaxial layer 120a according to the n-type blanket ion injection process.

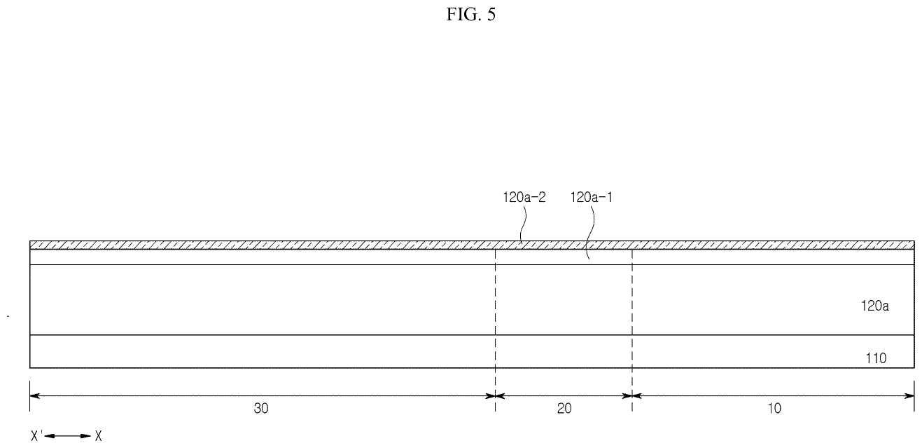

Referring to FIG. 5, it is possible to apply a photosensitive film 120a-2 on the surface of the first epitaxial layer 120a-1. In this instance, a thickness of the corresponding layer may be set to be about 6000 Å to about 8000 Å.

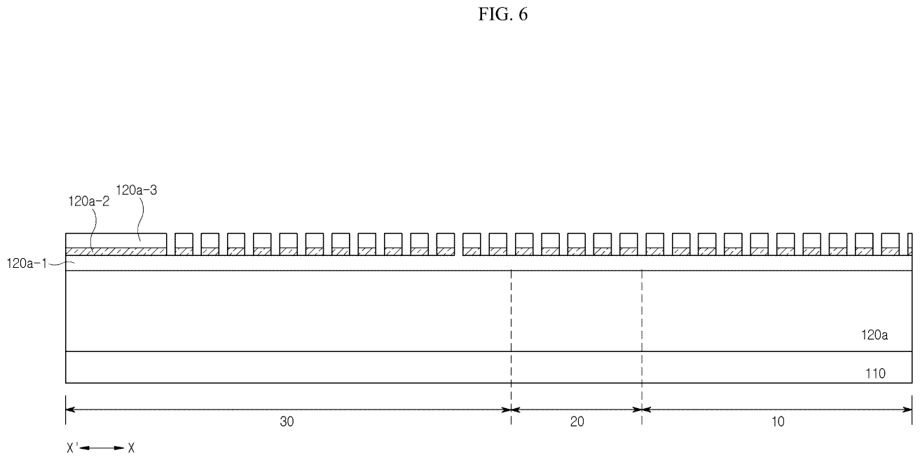

Referring to FIG. 6, a first mask 120a-3 may be applied on the photosensitive film 120a-2. The first mask may be patterned, and an ion of the second conductive type (e.g., p-type) may be injected into a portion exposed by the pattern of the first mask of the first epitaxial layer 120a.

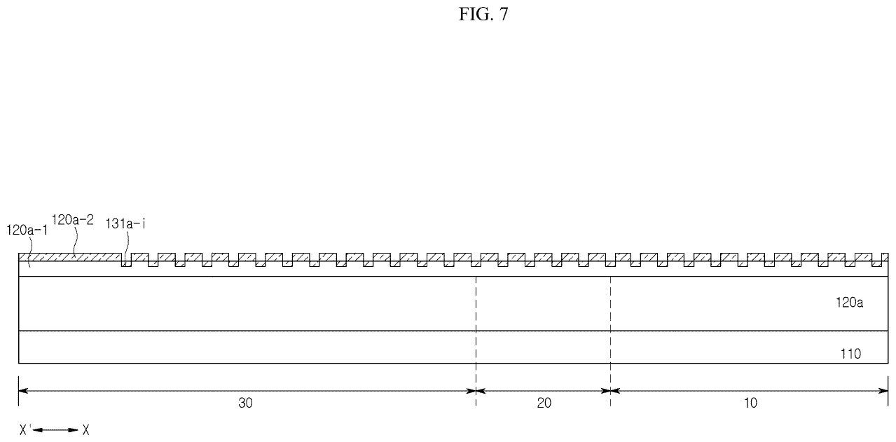

Referring to FIG. 7, it is possible to form a first implant layer 131a-i through the second conductive type ion injection. After forming the first implant layer 131a-i, the first mask 120a-3 may be removed.

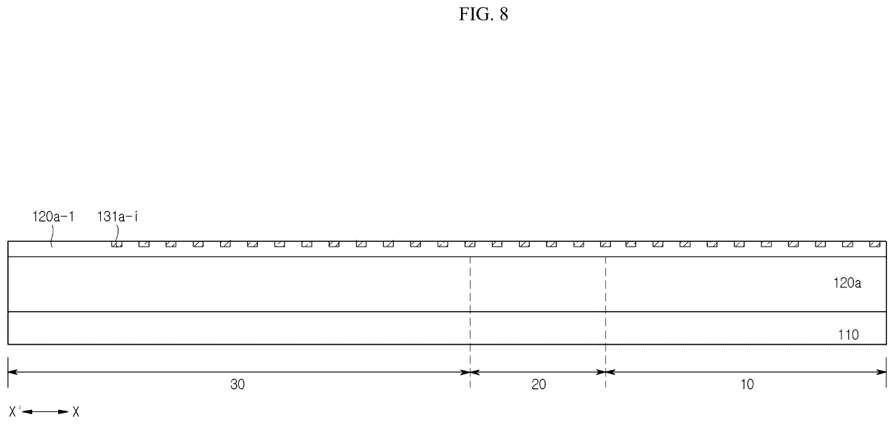

Referring to FIG. 8, the photosensitive film 120a-2 may be removed by conducting an ashing process. The process for forming the implant layer referring to FIGS. 4 to 8 may be applied the same to a process for forming a second to n-th epitaxial layers.

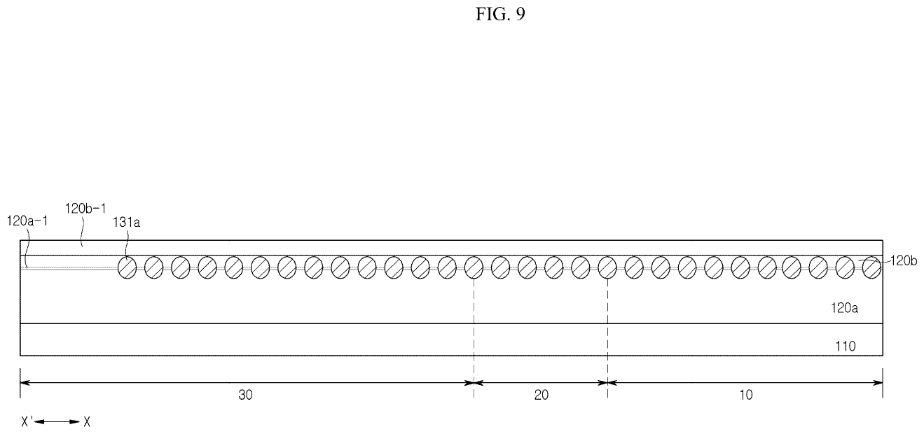

Referring to FIG. 9, a second epitaxial layer 120b may be formed on the surface of the first epitaxial layer 120a-1. A thickness of the second epitaxial layer 120b may be about 6.35% to 6.55% of the thickness of the overall epitaxial layer 120. An epitaxial process for forming the second epitaxial layer 130b may include an annealing process at a high temperature. Due to the annealing process at a high temperature used in the epitaxial process for forming the second epitaxial layer 120b, the first implant layer 131a-i is distributed and forms a p-type lower-first pillar layer 131a of the second conductive type. In a process where the first implant layer 131a-i is distributed, because of the n-type blanket ion positioned between pillar ion implant layers of the second conductive type, distribution of the pillar ions of the second conductive type in a left-right direction decreases and distribution thereof in the vertical direction increases, thereby forming a vertical type pillar structure.

When forming the second epitaxial layer 120b, the process temperature may be set to about 900 degrees to 1300 degrees. After forming the second epitaxial layer 120b, an injection process of a blanket ion of the first conductive type (e.g., n-type) may be conducted. By doing so, the concentration of the ions of the first conductive type may increase on a surface of the second epitaxial layer 120b-1.

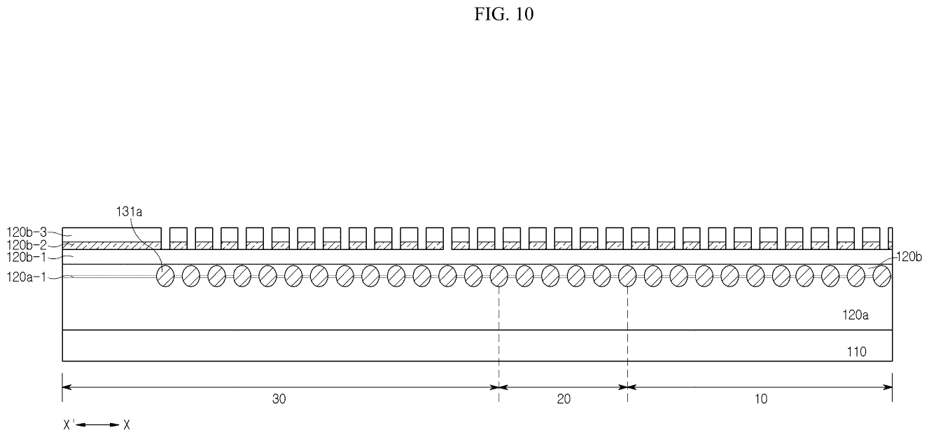

Referring to FIG. 10, a photosensitive film 120b-2 may be applied on the surface of the second epitaxial layer 120b-1, and a second mask 120b-3 may be disposed on the photosensitive film 120b-2 applied. The second mask may be patterned so that a portion subjected to be injected with the ion of the second conductive type in the second epitaxial layer 120b can be exposed. A process for injecting the p-type ion may be conducted on the mask pattern exposed on the second epitaxial layer 120b.

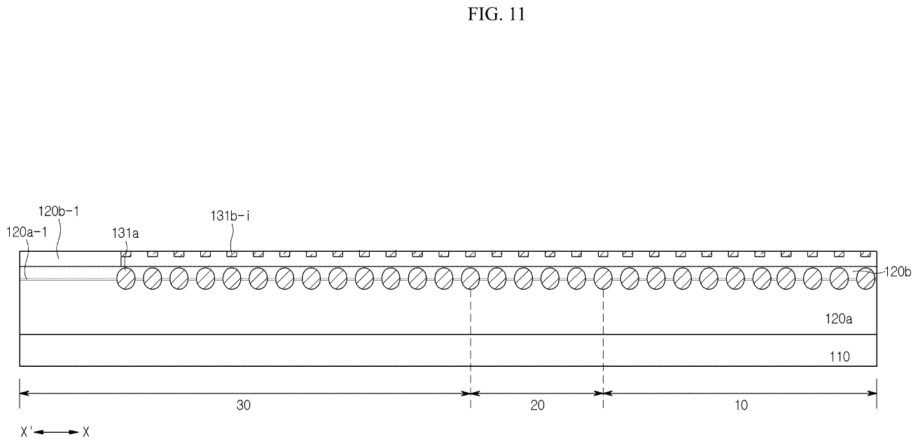

Referring to FIG. 11, after forming the second implant layer 131b-i, the second mask 120b-2 may be removed. In addition, by conducting the ashing process, the photosensitive film 120b-3 may be removed.

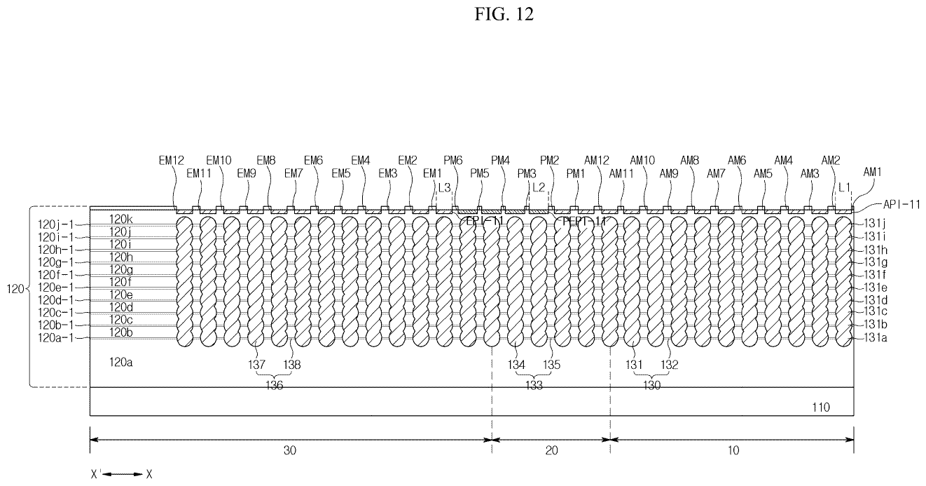

Referring to FIG. 12, by repeating the process described referring to FIGS. 5 and 11, the fifth to eleventh epitaxial layers 120l to 120k may be stacked and the third to tenth pillar layers 131a to 131j of the second conductive type may be formed.

According to an embodiment, mask patterns AM1 to AM12 are disposed in the active region, mask patterns PM1 to PM6 are disposed in the peripheral region, and mask patterns EM1 to EM12 are disposed in the edge termination region. An opening according to the mask pattern when forming the eleventh pillar layer around the boundary between the peripheral region and the edge termination region may be formed greater than an opening according to the mask pattern in the active region. The opening is a portion of a surface of the epitaxial layer exposed between the mask patterns, and a width of the opening L1 of the mask pattern in the active region and a width of the opening L3 of the mask pattern in the edge termination region are the same, and a width of the opening of the mask pattern L2 in the boundary between the peripheral region and the edge termination region is formed greater than the opening of the mask pattern in the active region and the opening of the mask pattern in the edge termination region, thereby forming a greater ion injection area. An eleventh pillar ion injection layer API-11 in the active region and an eleventh pillar ion injection layer EPI-11 in the edge termination region have ion injection areas having the same width, and a width of ion injection of an ion injection layer PEPI-11 near the boundary between the peripheral region and the edge termination region is formed greater than the width of the ion injection layers of the active region and the edge termination region. Accordingly, the eleventh pillar ion injection layer may have an ion amount injected near the boundary between the edge termination region and the peripheral region, which is greater than the ion amount injected into the active region. Because of this, it is possible to improve the ruggedness of the device by distributing an area on which the holes are concentrated in the edge termination region, and to prevent the lattice temperature from increasing around the surface of the epitaxial layer in the edge termination region. This is an effect obtainable by only using an additional process or a mask, but may be obtained through the ion injection process into the eleventh pillar layer.

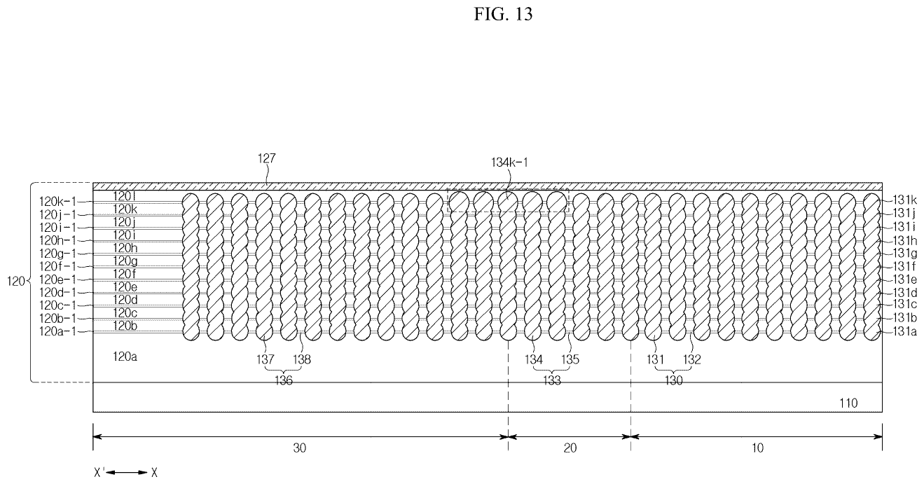

Referring to FIG. 13, the fourth to twelfth epitaxial layers 120d to 120l are stacked and the third to eleventh pillar layers 131c to 131k of the second conductive type may be formed by repeating the process described referring to FIGS. 5 to 11 and conducting the process in FIG. 12. The first to eleventh pillar layers 131a to 131k of the second conductive type may be distributed and connected as pillars in a vertical shape. In this instance, when it comes to the quantity of the epitaxial layers, n epitaxial layers may be formed.

The first to the eleventh pillar layers 131a to 131k formed in the active region 100 may be referred to as the first p-type pillar 131 in the first pillar region 130. The first n-type pillar 132 may be disposed between a plurality of first p-type pillars 131. The first to the eleventh pillar layers 131a to 131k formed in the peripheral region 20 may be referred to as the second p-type pillar 134 in the second pillar region 133. The second n-type pillar 135 may be disposed between a plurality of second p-type pillars 134. The first to the eleventh pillar layers 131a to 131k formed in the edge termination region 30 may be referred to as the third p-type pillar 137 in the third pillar region 136. The third n-type pillar 138 may be disposed between a plurality of third p-type pillars 137. The first to the third n-type pillars 138 may correspond to only a portion of the epitaxial layer 120 into which the p-type ion is not injected.

As described referring to FIG. 3a, the first pillar layer 131a to the third pillar layer 131c may be classified into the lower pillar regions 131a to 131c, the fourth pillar layer 131d to the ninth pillar layer 131i may be classified into the intermediate pillar region, and the tenth pillar layer 131j to the eleventh pillar layer 131k may be classified into the upper pillar region 131j to 131k.

According to an embodiment, when forming the eleventh pillar layer 131k, the openings according to the mask pattern in a portion where the edge termination region 30 and the peripheral region 20 contact each other may be formed greater than the opening according to the mask pattern in the active region 10. As the process illustrated in FIG. 12 is conducted, in the eleventh pillar layer 131k, the ion amount injected into the portion where the edge termination region 30 and the peripheral region 20 contact each other may be greater than the ion injected into the active region 10. Therefore, an eleventh-1 pillar layer 134k-1 of the portion where the edge termination region 30 and the peripheral region 20 contact each other may have a greater amount of p-type ion than another portion in the eleventh pillar layer 131k. Through this configuration, it is possible to improve the ruggedness of the device by distributing the area where holes are concentrated in the edge termination region 30, and to prevent the lattice temperature from increasing in the edge termination region. This effect can be obtained by using an additional mask, but through the described process, it is possible to obtain these effects.

After forming the twelfth epitaxial layer 120l, a cleaning process using hydrofluoric acid (HF) may be performed so as to remove naturally formed oxide. After the cleaning process, a sacrificial oxide layer 127 may be formed and then removed so as to recover the rough surface obtained as a result of going through the cleaning process to the flat state. Then, the n-type blanket ion injection process may be additionally conducted. According to another embodiment, it is possible to form a sixth epitaxial layer 120f and after conducting the process for injecting the n-type blanket ion, the cleaning process may be conducted and the sacrificial oxide layer 127 may be formed. The sacrificial oxide layer 127 may recover damage or an uneven portion formed on the surface of the epitaxial layer 120. After the recovery, the sacrificial oxide layer 127 may be removed.

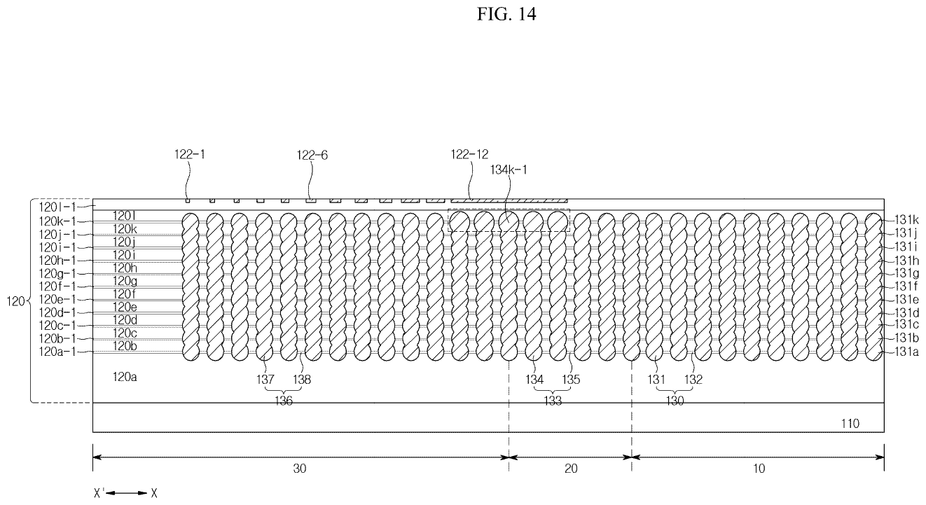

Referring to FIG. 14, after forming the twelfth epitaxial layer 120l, the process for injecting the n-type blanket ion into the twelfth epitaxial layer is conducted and a twelfth mask (not illustrated) may be disposed on a surface of the twelfth epitaxial layer 120l-1. Portions 122-1 to 122-12 into which the ion of the second conductive type is injected may be exposed on the surface of the twelfth epitaxial layer 120l-1 by patterning the twelfth mask. An edge termination ion injection layer of the second conductive type is formed by conducting the process for injecting the ion of the second conductive type on the exposed mask patterns on the twelfth epitaxial layer 120l, and the twelfth mask may be removed. Here, the layers 122-1 to 122-12 into which the ion of the second conductive type is injected may have widths that gradually become greater from the edge termination region to the peripheral region. That is, from the first edge termination ion injection layer 122-1 of the second conductive type to the sixth edge termination ion injection layer 122-6 of the second conductive type, the widths become greater, and from the sixth edge termination ion injection layer 122-6 of the second conductive type to the twelfth edge termination ion injection layer 122-12 of the second conductive type, the widths become even greater.

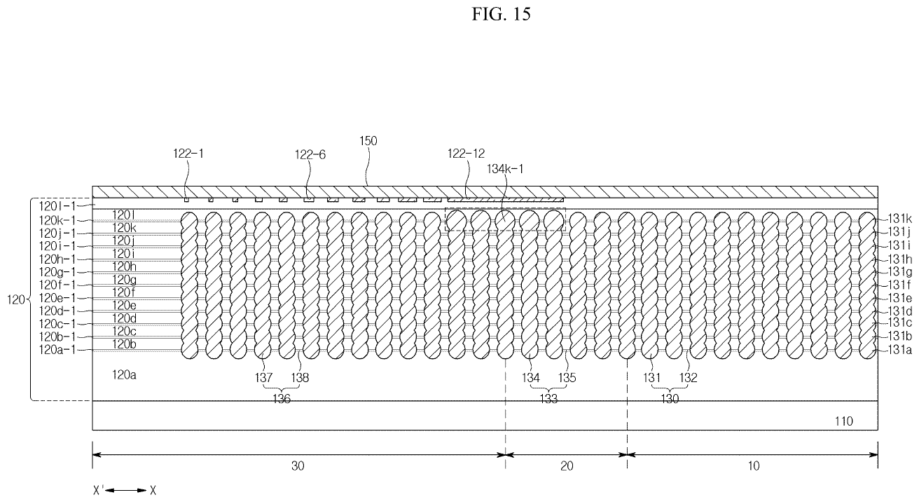

Referring to FIG. 15, the field oxide layer 150 may be formed on a surface of the epitaxial layer 120 on which the twelfth implant layer is formed in the edge termination region 30 and the peripheral region 20.

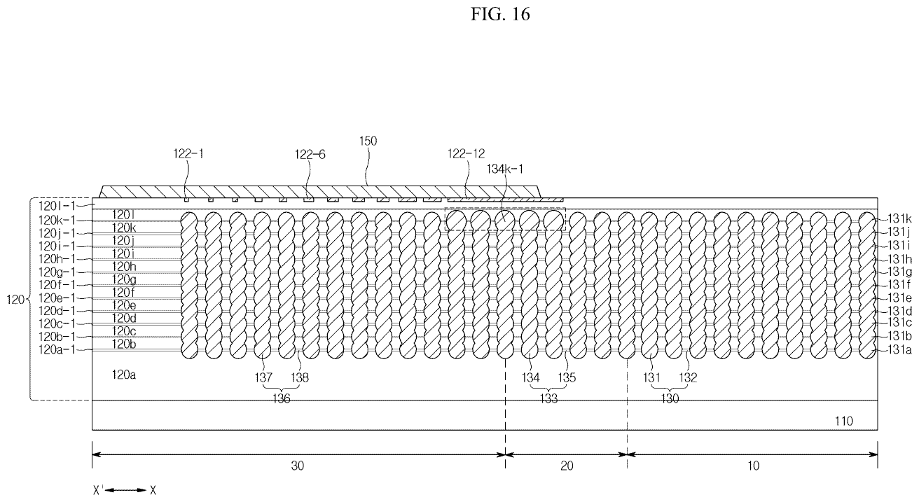

Referring to FIG. 16, after depositing the field oxide layer 150 on the whole surface of the epitaxial layer 120, by disposing a mask on the field oxide layer 150 and patterning the mask, a remaining region except the field oxide layer 150 in the edge termination region 30 and the peripheral region 20 may be etched.

The field oxide layer 150 may be formed through an oxidation process, and a material of the oxide layer may be silicon oxide, silicon oxynitride, silicon nitride and the like.

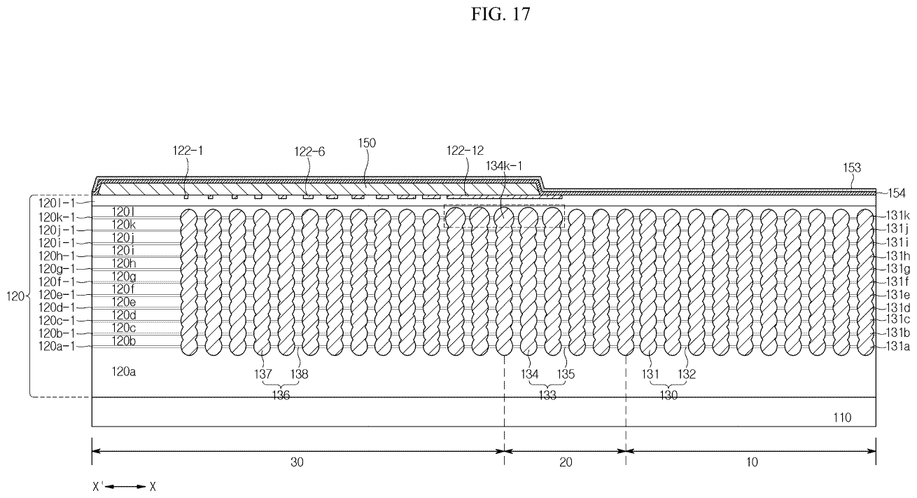

Referring to FIG. 17, according to an embodiment, the gate insulation layer 154 may be deposited over the whole area of the active region 10, the peripheral region 20, and the edge termination region 30. In addition, a metal layer may be deposited on the gate insulation layer 154 so as to form the gate electrode 153.

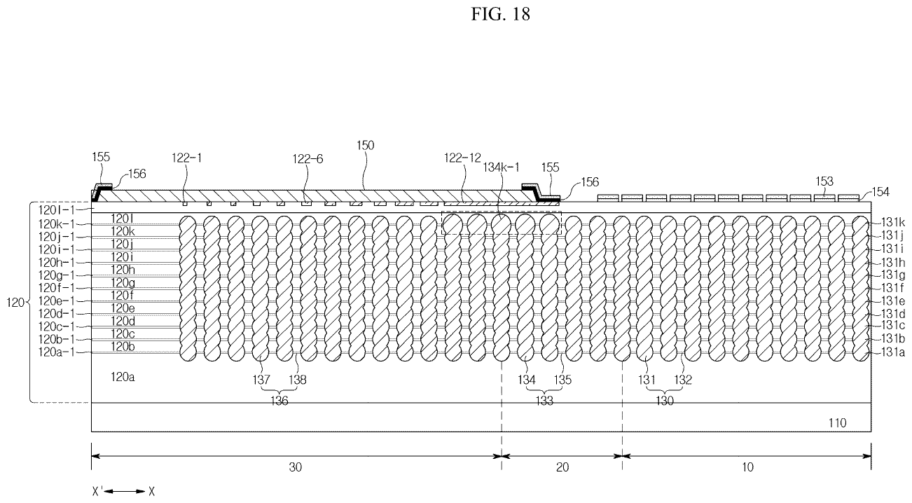

Referring to FIG. 18, according to an embodiment, by etching the metal layer for forming the gate insulation layer 154 and the gate electrode 153, the gate electrode 153, the gate insulation layer 154, the field plate 155, and a field plate insulation layer 156 may be formed.

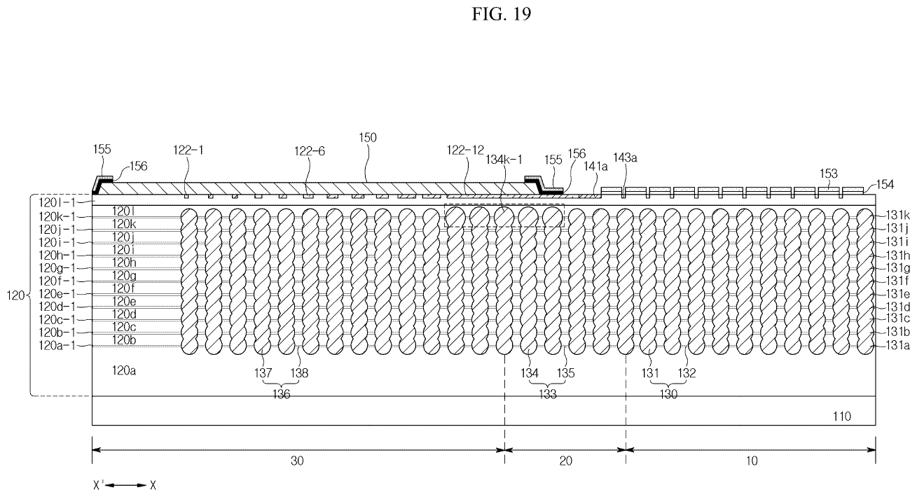

Referring to FIG. 19, as described referring to FIGS. 17 and 18, the gate insulation layer 154, the gate electrode 153, the field plate 155, and the field plate insulation layer 156 may be formed.

In this instance, as described referring to FIG. 17, the field plate insulation layer 156 and the gate insulation layer 154 may be deposited and formed at the same time. According to an embodiment, the insulation layer may be deposited over the whole area of the active region 10, the peripheral region 20, and the edge termination region 30. As described referring to FIG. 18, the gate insulation layer 154, the gate electrode 153, the field plate insulation layer 156, and the field plate 155 may be formed by depositing polysilicon on the insulation layer, and etching the insulation layer and the polysilicon layer together.

The field plate 155 may be formed on the field oxide layer 150 and the field plate insulation layer 156 in the edge termination region 30. The field plate insulation layer 156 below the field plate 155 is formed of the same material as that of the gate insulation layer 154, and therefore, as illustrated in FIG. 19, they may be referred to as the same gate insulation layer 154. The field plate 155 may be formed on the gate insulation layer 154 (the field plate insulation layer 156) and on a side surface and an upper surface of the field oxide layer 150 disposed in the boundary region between the edge termination region 30 and the peripheral region 20.

The gate electrode 153 may be formed on the gate insulation layer 154 in the active region 10. The gate electrode 153 may be formed on the gate insulation layer in the boundary between the active region 10 and the peripheral region 20.

In addition, by conducting the process for injecting ions of the second conductive type, ion injection layers 143a and 141a of the second conductive type may be formed in the active region 10 and the peripheral region 20. By using the gate electrode 153 and the field plate 155 as masks, the process may be simplified, and process expenses may be reduced. Such a process for injecting ions of the second conductive type may be referred to as a P-well ion injection process.

A concentration of the impurities 141a and 143a of the second conductive type injected in the process for injecting ions of the second conductive type may be higher than a concentration of the impurity of the second conductive type injected into the ion injection layer 122 in the edge termination charge-sharing region.

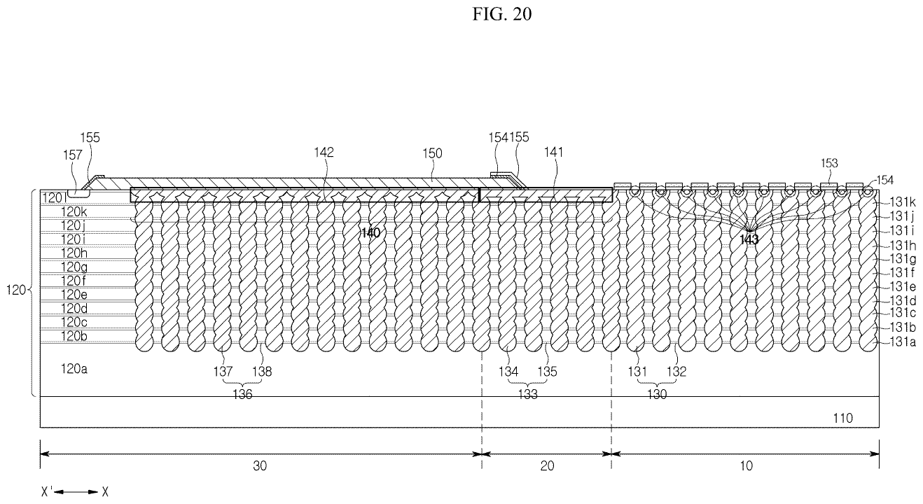

Referring to FIG. 20, by distributing the ion of the second conductive type injected into the ion injection layer 122 in the edge termination charge-sharing region, the active region 10, and the peripheral region 20 through the annealing process, the edge termination charge-sharing region 142, the peripheral charge-sharing region 141, and the body region 143 may be formed. The edge termination charge-sharing region 142, the peripheral charge-sharing region 141, and the body region 143 may spread onto the surface of the epitaxial layer 120 through thermal spread. In addition, the edge termination charge-sharing region 142 may be connected to upper layers of the third p-type pillars 137 in the third pillar region 136 formed in the edge termination region 30. The peripheral charge-sharing region 141 may be connected to upper layers of the second p-type pillars 134 in the second pillar region 133 formed in the peripheral region 20. In addition, the body region 143 may be connected to upper layers of the first p-type pillars 131 in the first pillar region 130 formed in the active region 10. The peripheral charge-sharing region 141 and the edge termination charge-sharing region 142 may spread to be connected to each other.

During the annealing process, the temperature may be about 1000 degrees to 1300 degrees, and the process time may be 100 minutes to 200 minutes. The annealing process at a high temperature may distribute the first to the third pillar regions 130, 133 and 136 sufficiently and may form a pillar structure in a more stable vertical shape, thereby a higher breakdown voltage may be secured.

It is possible to simplify processes and reduce process expenses by using the gate electrode 153 and the field plate 155 as masks, and by conducting the process for distributing ions through the annealing in the active region 10, the peripheral region 20, and the edge termination region 30 at the same time. The process for injecting ions of the second conductive type may be referred to as the P-well ion injection process.

The charge-sharing region 140 may be referred to as the p-top layer region.

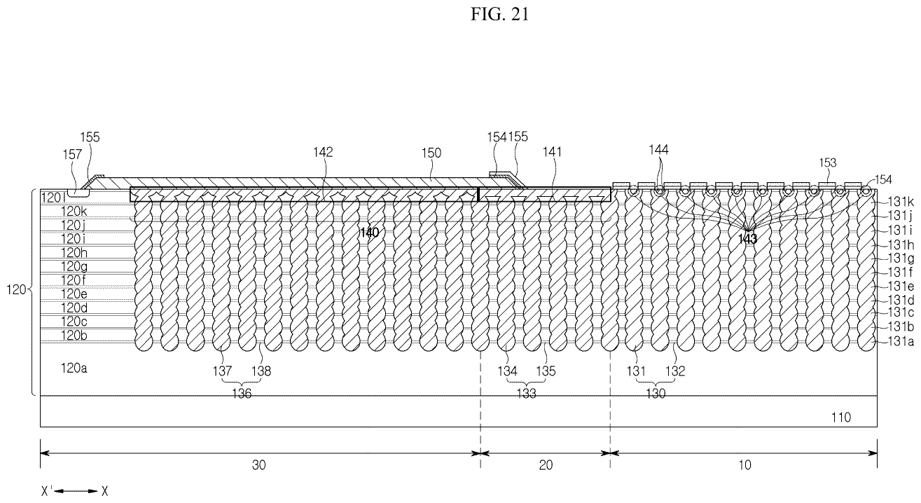

Referring to FIG. 21, the source region 144 may be formed by only exposing a portion for forming the source region 144 through the patterning process after disposing the mask between the gate electrode 153 formed in the active region 10, and conducting the process for injecting the source ion. The source region 144 may spread onto and may be formed on some region below the gate electrode 153.

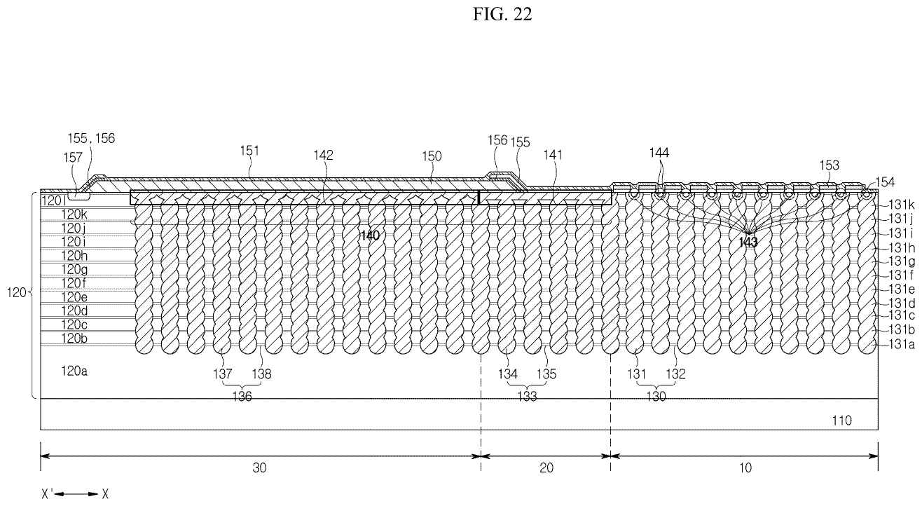

Referring to FIG. 22, a first insulation layer 151 may be formed on the gate electrode 153, the field plate 155, and the field oxide layer 150. The first insulation layer 151 may be referred to as a spacer, and may be formed by using materials such as a silicon oxide (SiO2) layer, a silicon nitride (SiN) layer, a silicon oxynitride (SiON) layer, and a nitride layer, etc. A deposition thickness of the first insulation layer 151 may be about 800 Å to about 2000 Å.

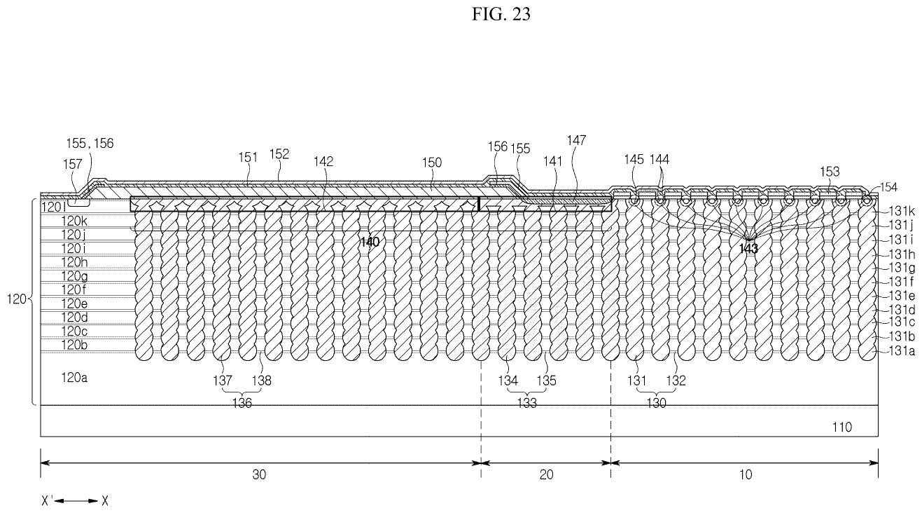

Without disposing an additional mask on the first insulation layer 151, the process for injecting the blanket ion of the second conductive type having a high concentration may be conducted. Accordingly, a body contact ion injection layer and a peripheral charge sharing contact ion injection layer may be formed in the active region 10. The body contact ion injection layer may become the body contact region 145 of the second conductive type, and the peripheral charge sharing contact ion injection layer may become the peripheral contact region 147, by conducting a process to be described referring to FIG. 23.

The first insulation layer 151 is formed to be thicker on the source region 144 in the active region 10, and the ion injection may not be done to the source region 144 when conducting the process for injecting the blanket ion of the second conductive type. In the prior art, a mask for blocking the source region 144 has been additionally disposed; however, in the present disclosure, the body contact ion injection layer may be formed by conducting the process for injecting the blanket ion of the second conductive type having a high concentration, without disposing an additional mask for protecting the source region 133 after forming the first insulation layer 151, thereby the processes are simplified and processing expenses are reduced.

Referring to FIG. 23, the second insulation layer 152 may be deposited on the first insulation layer 151. After depositing the second insulation layer 152, a thermal process may be conducted for planarizing the second insulation layer 152. Because of the thermal process, the body contact ion injection layer may be formed as the body contact region 145 of the second conductive type, and the peripheral charge sharing contact ion injection layer may be formed as the peripheral contact region 147.

The second insulation layer 152 may be formed as a layer of BPSG (boron-phosphors silicate glass) or PSG (phosphors silicate glass).

A deposition thickness of the second insulation layer 152 may be about 8000 Å to 12000 Å.

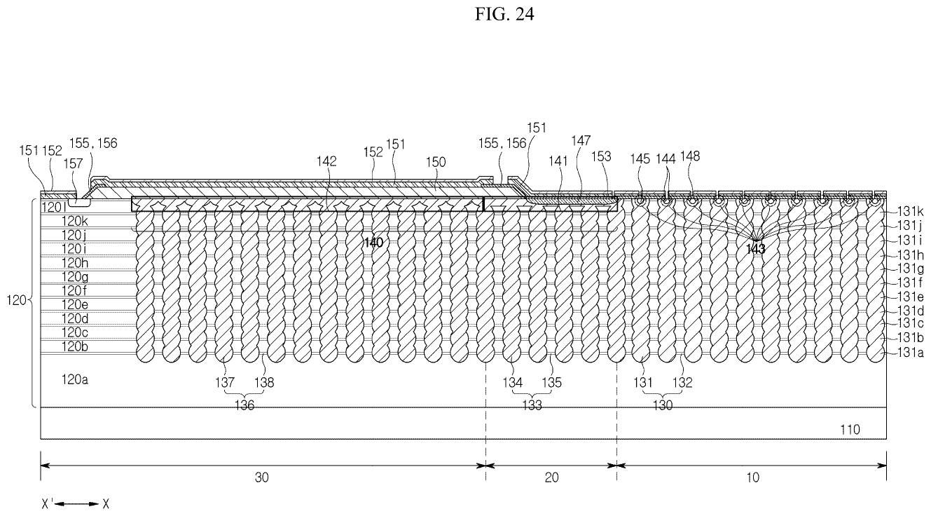

Referring to FIG. 24, by conducting a contact etching on the first insulation layer 151 and the second insulation layer 152, the source contact region 148, the peripheral contact region 147, the body contact region 145, and a gate runner contact region may be formed or may be exposed to the surface of the device. By patterning the contact mask after disposing the contact mask on the first insulation layer 151 and the second insulation layer 152, and then by etching the first insulation layer 151 and the second insulation layer 152, it is possible to expose the contact regions. As a result, the body contact region 145 in the active region 100 is exposed, and the gate runner contact region may be formed on the field plate 155 in the edge termination region 30. As the peripheral contact region 147 becomes greater, the contacted area becomes greater as well, thereby the resistance can be further reduced.

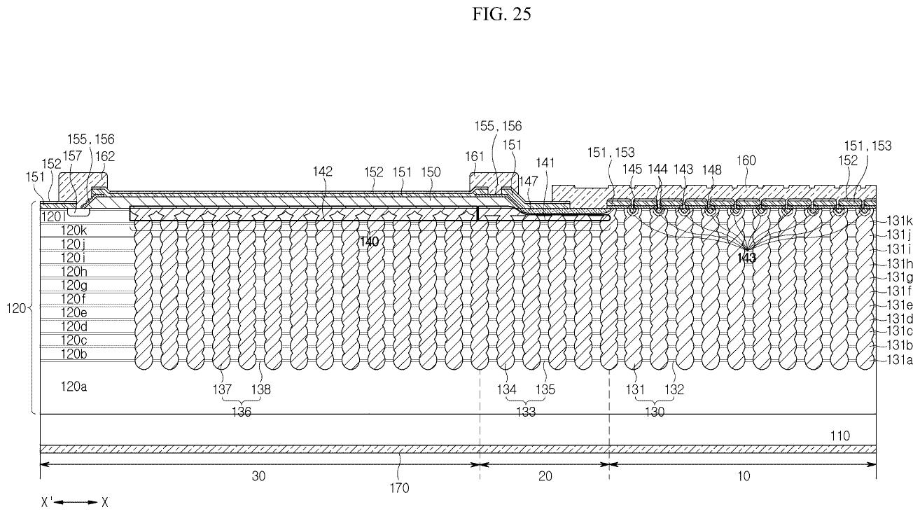

Referring to FIG. 25, the metal layer may be deposited on the regions on which the contact etching is conducted. After that, the deposited metal layer may be planarized by conducting the planarization process. The metal layer may be planarized through the CMP process. The metal etching process may be conducted by disposing the mask on the planarized metal layer and patterning the metal layer. After conducting the metal etching process, the source electrode 160 connected to the source contact region 148 and the peripheral contact region 147 may be formed. In addition, the gate runner 161 connected to the field plate 155 may be formed. Moreover, the floating electrode 162 may be formed at a tip end of the edge termination region 30.

During the process for forming the metal layer, by depositing titanium (Ti) or titanium nitride serving as a metal barrier first, then depositing tungsten (W) inside the contact hole, and then depositing an aluminum (AI) layer on the tungsten layer deposited, the metal layer may be formed.

Next, a thickness of the substrate 110 may be reduced by conducting a back grinding process as a process for grinding the substrate 110. The process for grinding the substrate 110 may reduce the thickness of the substrate 110, thereby reducing a resistance inside the substrate 110.

Next, the lower metal layer may be formed. The lower metal layer may serve as the drain electrode 170. The lower metal layer may be formed of nickel-vanadium, silver, and the like.

By conducting the above-described processes, it is possible to form the super junction semiconductor device capable of securing a proper breakdown voltage and securing a high slope value of the reverse recovery current desired when the reverse bias is applied.

One or more embodiments of the present disclosure aim to ease the gate oscillation at the time of the switching operation by preventing fast expansion of the n-pillar depletion layer while maintaining the existing basis that is to increase productivity through differentiation of the gradient of a dopant concentration of each epitaxial layer disposed on the substrate.

One or more embodiments of the present disclosure aim to ease a gate turn-off oscillation by reducing dv/dt of the device through increase of ripple of the pillars while minimizing inefficiency of the process by differentiating thicknesses of some epitaxial layers.

One or more embodiments of the present disclosure aim to improve ruggedness of the diode by allowing an area of an opening region of a mask layout of some pillar structure in a termination region at a portion where the termination region and a peripheral region contacts each other to be wider than a corresponding pillar structure in an active region.

According to one or more embodiments of the present disclosure, it is possible to ease the gate oscillation at the time of the switching operation by preventing fast expansion of the depletion layer of the first conductive type pillar while maintaining the conventional basis of increasing productivity through differentiation of the gradient of the dopant concentration of the epitaxial layer.

According to one or more embodiments of the present disclosure, it is possible to decrease variation of the process compared to an existing method of utilizing a doped epitaxial layer, by using a process to inject the ion into the intrinsic epitaxial layer.

According to one or more embodiments of the present disclosure, it is possible to improve the gate turn-off oscillation which is a conventional problem, by increasing a ripple value of the pillar by forming a layer below an uppermost layer of the plurality of epitaxial layers to be greater than other epitaxial layers and reducing dv/dt of the device.

According to one or more embodiments of the present disclosure, it is possible to improve the ruggedness of the diode by forming an area of the opening region of a mask layout of a pillar structure which is directly below an uppermost layer of the termination region at a portion where the termination region contacts the peripheral region to be greater than the pillar directly below an uppermost layer of the active region.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A super junction semiconductor device, comprising:
a substrate;
a plurality of epitaxial layers disposed on the substrate;
an active region disposed on one region of the substrate and the epitaxial layer;
a peripheral region and an edge termination region surrounding the active region; and
a plurality of first conductive type pillar regions and a plurality of second conductive type pillar regions disposed in the plurality of epitaxial layers, respectively,
wherein each of the plurality of first conductive type pillar regions and the plurality of second conductive type pillar regions in the active region is divided into a lower pillar region, an intermediate pillar region, and an upper pillar region, sequentially,
wherein a dopant concentration gradually increases from the lower pillar region to the intermediate pillar region, and
wherein another dopant concentration gradually decreases from the intermediate pillar region to the upper pillar region.

2. The super junction semiconductor device of claim 1,
wherein a dopant concentration of the lower pillar region of the first conductive type pillar region is greater than a dopant concentration of the upper pillar region of the first conductive type pillar region, and
wherein a dopant concentration of the lower pillar region of the second conductive type pillar region is greater than a dopant concentration of the upper pillar region of the second conductive type pillar region.

3. The super junction semiconductor device of claim 1,
wherein each of the lower pillar region of the first conductive type pillar region and the lower pillar region of the second conductive type pillar region is divided into a lower pillar layer, an intermediate pillar layer, and an upper pillar layer,
wherein a dopant concentration of the lower pillar layer of the lower pillar region of the first conductive type pillar region is lower than a dopant concentration of the intermediate pillar layer of the lower pillar region of the first conductive type pillar region, and
wherein dopant concentrations of the lower pillar layer, the intermediate pillar layer, and the upper pillar layer of the lower pillar region of the second conductive type pillar region are the same.

4. The super junction semiconductor device of claim 1,
wherein each of the intermediate pillar region of the first conductive type pillar region and the intermediate pillar region of the second conductive type pillar region is divided into a lower pillar layer, an intermediate pillar layer, and an upper pillar layer,
wherein a dopant concentration of the intermediate pillar layer of the intermediate pillar region of the first conductive type pillar region is greater than a dopant concentration of the lower pillar layer and the upper pillar layer of the intermediate pillar region of the first conductive type pillar region, and
wherein a dopant concentration of the intermediate pillar layer of the intermediate pillar region of the second conductive type pillar region is greater than the lower pillar layer and the upper pillar layer of the intermediate pillar region of the second conductive type pillar region.

5. The super junction semiconductor device of claim 1, further comprising:
a second conductive type charge-sharing region, formed in the peripheral region and the edge termination region, connected to the upper pillar region in the second conductive type pillar region.

6. The super junction semiconductor device of claim 1,
wherein each of the upper pillar region of the first conductive type pillar region and the upper pillar region of the second conductive type pillar region is divided into a lower pillar layer and an upper pillar layer,
wherein the upper pillar layer of the upper pillar region of the second conductive type pillar region in the active region comprises a second conductive type body region, and
wherein a dopant concentration of the lower pillar layer of the upper pillar region of the first conductive type pillar region and the second conductive type pillar region is greater than a dopant concentration of the upper pillar layer of the upper pillar region of the first conductive type pillar region and the second conductive type pillar region.

7. The super junction semiconductor device of claim 6,
wherein a thickness of the upper pillar layer of the upper pillar region of the first conductive type pillar region and the second conductive type pillar region is greater than a thickness of the lower pillar layer of the upper pillar region of the first conductive type pillar region and the second conductive type pillar region.

8. The super junction semiconductor device of claim 6,
wherein a width of the upper pillar layer of the upper pillar region of the second conductive type pillar region in a boundary portion between the edge termination region and the peripheral region is greater than a width of the upper pillar layer of the upper pillar region of the second conductive type pillar region in the active region.

9. A method for manufacturing a super junction semiconductor device, comprising:
forming a lower pillar region by forming a plurality of lower epitaxial layers on a semiconductor substrate having an active region, a peripheral region, and an edge termination region, and by alternately forming a first conductive type pillar and a second conductive type pillar through a first ion injection process within the plurality of lower epitaxial layers;
forming an intermediate pillar region of a first conductive type pillar and a second conductive type pillar in the lower pillar region by forming a plurality of intermediate epitaxial layers on the plurality of lower epitaxial layers, and conducting a second ion injection process within the plurality of intermediate epitaxial layers; and
forming an upper pillar region of a first conductive type pillar and a second conductive type pillar in the intermediate pillar region by forming a plurality of upper epitaxial layers on the plurality of intermediate epitaxial layers and conducting a third ion injection process within the plurality of upper epitaxial layers,
wherein a dopant concentration of the intermediate pillar region is greater than a dopant concentration of the lower pillar region and a dopant concentration of the upper pillar region.

10. The method of claim 9, further comprising:
forming an ion injection region on the upper pillar region of the first conductive type pillar and the second conductive type pillar formed in the edge termination region;
forming an ion injection region on the upper pillar region of the first conductive type pillar and the second conductive type pillar formed in the peripheral region; and
forming a charge-sharing region by dispersing the ion injection region in each of the edge termination region and the peripheral region.

11. The method of claim 9,
wherein the forming of the lower pillar region comprises forming a lower pillar layer, an intermediate pillar layer, and an upper pillar layer in the lower pillar region and allowing a dopant concentration of the intermediate pillar layer to be greater than a dopant concentration of the lower pillar layer.

12. The method of claim 9,
wherein the forming of the intermediate pillar region comprises forming a lower pillar layer, an intermediate pillar layer, and an upper pillar layer in the intermediate pillar region and allowing a dopant concentration of the intermediate pillar region to be greater than dopant concentrations of the lower pillar layer and the upper pillar layer.

13. The method of claim 12, further comprising:
allowing a dopant concentration of the upper pillar layer to be greater than a dopant concentration of the lower pillar layer.

14. The method of claim 9,
wherein the forming of the upper pillar region comprises forming a lower pillar layer and an upper pillar layer on the upper pillar region and allowing a dopant concentration of the lower pillar layer to be greater than a dopant concentration of the upper pillar layer.

15. The method of claim 14,
wherein the forming of the lower pillar layer and the upper pillar layer on the upper pillar region comprises forming a thickness of the lower pillar layer to be thicker than a thickness of the upper pillar layer.

16. The method of claim 14,
wherein the forming of the lower pillar layer and the upper pillar layer on the upper pillar region comprises:
forming a mask on the lower pillar layer;
forming a plurality of openings by patterning the mask in the active region, the peripheral region, and the edge termination region, and forming an area of the plurality of openings in a boundary portion between the peripheral region and the edge termination region to be greater than an area of the plurality of openings of the active region; and
forming a width of the upper pillar layer of a second conductive type in the edge termination region and the peripheral region to be greater than a width of the upper pillar layer of a second conductive type in the active region by conducting the second ion injection process within the plurality of openings.

17. The method of claim 9,
wherein the forming of the lower pillar region comprises forming an epitaxial layer on which the lower pillar region is formed as an intrinsic epitaxial layer, and
wherein the forming of the intermediate pillar region comprises forming an epitaxial layer on which the intermediate pillar region is formed as an intrinsic epitaxial layer, and
wherein the forming of the upper pillar region comprises forming an epitaxial layer of which the upper pillar region allows the lower pillar layer and the upper pillar layer to be formed thereon as an intrinsic epitaxial layer.

18. A super junction semiconductor device, comprising:
a substrate;
a plurality of epitaxial layers formed on the substrate; and
a plurality of first conductive type pillars and a plurality of second conductive type pillars formed perpendicular to the substrate within the plurality of the epitaxial layers, and alternately disposed in a horizontal direction with respect to the substrate,
wherein the plurality of epitaxial layers are divided into a lower pillar region, an intermediate pillar region, and an upper pillar region, and
wherein a thickness of one epitaxial layer of the plurality of epitaxial layers in the upper pillar region is greater than a thickness of another epitaxial layer of the plurality of epitaxial layers in the upper pillar region.

19. The super junction semiconductor device of claim 18,
wherein the lower pillar region is divided into a lower pillar layer, an intermediate pillar layer, and an upper pillar layer each formed of a plurality of epitaxial layers, and
wherein a thickness of the lower pillar layer is greater than thicknesses of the intermediate pillar layer and the upper pillar layer.

20. The super junction semiconductor device of claim 18,
wherein the intermediate pillar region is divided into a lower pillar layer, an intermediate pillar layer, and an upper pillar layer each formed of a plurality of epitaxial layers, and
wherein thicknesses of the lower pillar layer, the intermediate pillar layer and the upper pillar layer are the same.
